(19) United States
(12) Patent Application Publication
(10) Pub. No.: US 2012/0223781 A1
(43) Pub. Date: Sep. 6, 2012

(54) NOISE REGULATED LINEAR VOLTAGE CONTROLLED OSCILLATOR

(75) Inventors: HaoQiong Chen, (US); Zhengxin Cao, (US); Qi Jian Ge, (US)

(73) Assignee: LSI Corporation

(21) Appl. No.: 13/037,774

(22) Filed: Mar. 1, 2011

(51) Int. Cl. H03B 5/00

(52) U.S. Cl. 331/108 D

(57) ABSTRACT

Described embodiments provide a voltage controlled oscillator (VCO) that includes an operational amplifier (opamp). The opamp has a positive power supply input coupled to a power supply voltage, a negative power supply input coupled to a ground node, an inverting input coupled to a control voltage of the VCO, a noninverting input that receives a feedback signal, and an output providing a transistor control voltage. A transistor having a gate terminal coupled to the output of the opamp, a source terminal coupled to the power supply voltage, and a drain terminal coupled to a resistor coupled to ground, generates an output current. A current mirror generates a mirror current based on the output current. A current controlled oscillator (ICO) is coupled to the current mirror, and sets the frequency of the VCO output signal based upon the mirror current.

### BACKGROUND OF THE INVENTION

1. Field of the Invention

The present invention relates to electronic circuits and, in particular, to a voltage controlled oscillator.

2. Description of the Related Art

Oscillators tunable over a defined frequency range are commonly employed in a variety of electronic applications, such as to generate modulated signals in communications systems. Tunable oscillators are frequently employed in a phase-locked loop (PLL). FIG. 1 shows a typical PLL, PLL 100, having phase detector 102, charge pump 104, loop filter 106, tunable oscillator 108, and frequency divider 110. PLL 100 provides an output frequency signal based upon an input reference frequency signal. Phase detector 102 compares the phase of the output frequency (or a divided-down output frequency) to the reference frequency to generate a phase error signal corresponding to the difference between the reference frequency and the output frequency. The phase error signal from phase detector 102 is used to adjust the frequency of oscillator 108, by causing charge pump 104 to adjust its output current based on the phase error signal. Loop filter 106 might be employed to smooth the output current from charge pump 104, and, if the tunable oscillator is a voltage controlled oscillator (VCO), loop filter 106 might also convert the output current of charge pump 104 to an input voltage to oscillator 108. This feedback loop generated control signal applied to tunable oscillator 108 allows PLL 100 to keep the phases of the reference frequency and the output frequency matched, which allows PLL 100 to closely track the input frequency, or to generate a frequency that is a multiple of the input frequency when frequency division by frequency divider 110 is employed in the feedback loop. PLLs are commonly used in communication systems for modulation, demodulation, frequency synthesis and signal recovery.

Two types of tunable oscillators that might be commonly employed in PLL 100 are a voltage controlled oscillator (VCO) and a current controlled oscillator (ICO). A VCO is an electronic oscillating circuit having an oscillation frequency controlled by a voltage input. A VCO desirably would have low power supply noise sensitivity, low phase noise, low variation of control voltage gain (Kvco), a wide frequency range, low power consumption, and compact design size. To achieve low supply noise sensitivity, a typical VCO might rely on noise rejection characteristics (the power supply rejection ratio or PSRR) of a voltage regulator that supplies power to the VCO. Commonly, the frequency gain of the supply voltage (Kvdd) is close to the frequency gain of the control voltage (Kvco).

Modern VCO applications are often in low operating voltage environments, thus limiting the control voltage and the supply voltage provided to the VCO, which in turn, limits the frequency range of the VCO. Increasing the control voltage frequency gain (Kvco) or the supply voltage frequency gain (Kvdd) of the oscillator is typically undesirable since a small voltage ripple could then result in a large jitter in the frequency of the oscillator. Further, process, voltage and temperature (PVT) variations might cause Kvco to vary, which can cause jitter peaking in the PLL transfer function and degrade stability of a PLL employing the VCO.

To improve the stability of a VCO for a given frequency range, frequency calibration might be employed. Frequency calibration sets a free-running (“open loop”) frequency of the VCO as close as possible to a desired frequency before the PLL locks on to the frequency (“closed loop”). Further, during frequency calibration, the VCO control voltage might be set to the middle of the supply voltage range, which might result in improved frequency range of the VCO, as well as improving performance of the charge pump of the PLL, thus improving jitter performance of the PLL.

### SUMMARY OF THE INVENTION

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Described embodiments provide a voltage controlled oscillator (VCO) that includes an operational amplifier (opamp). The opamp has a positive power supply input coupled to a power supply voltage, a negative power supply input coupled to a ground node, an inverting input coupled to a control voltage of the VCO, a noninverting input that receives a feedback signal, and an output providing an output voltage. A transistor having a gate terminal coupled to the output of the opamp, a source terminal coupled to the power supply voltage, and a drain terminal coupled to a resistor coupled to ground, generates an output current. A current mirror generates a mirror current based on the output current. A current controlled oscillator (ICO) is coupled to the current mirror, and sets the frequency of the VCO output signal based upon the mirror current.

### BRIEF DESCRIPTION OF THE DRAWINGS

Other aspects, features, and advantages of the present invention will become more fully apparent from the following detailed description, the appended claims, and the accompanying drawings in which like reference numerals identify similar or identical elements.

FIG. 1 shows a block diagram of a prior art phase locked loop (PLL) circuit;

FIG. 2 shows a schematic diagram of a voltage controlled oscillator (VCO), in accordance with exemplary embodiments of the present invention;

FIG. 3 shows a flow diagram of a frequency calibration process for the VCO of FIG. 2;

FIG. 4 shows a schematic diagram of a delay cell of a current controlled oscillator of the VCO of FIG. 2, in accordance with exemplary embodiments of the present invention;

FIG. 5 shows an exemplary graph of the VCO running frequency versus the control voltage, or the control voltage gain (Kvco) of the VCO of FIG. 2;

FIG. 6 shows an exemplary graph of the supply voltage gain (Kvdd) versus the supply noise frequency of the VCO of FIG. 2;

FIG. 7 shows an exemplary graph of the normalized (Kvdd) versus the supply noise frequency of the VCO of FIG. 2 for three exemplary cases; and

FIG. 8 shows an exemplary graph of the phase noise versus the frequency of the VCO of FIG. 2.

### DETAILED DESCRIPTION

Described embodiments of the present invention provide for a noise-regulated linear voltage controlled oscillator (NRL VCO) employing a unity gain operational amplifier (opamp) in conjunction with a current controlled oscillator (ICO). The opamp provides power supply rejection ratio (PSRR) for the NRL VCO, thereby allowing for relatively high power supply noise rejection, and the ICO provides for linear operation of the NRL VCO. Relatively high accuracy frequency calibration is provided via an adjustable current mirror supply for the ICO. Embodiments of the present invention also achieve relatively low frequency modulation bandwidth, low control voltage ripple and low phase noise.

Table 1 summarizes a list of acronyms employed throughout this specification as an aid to understanding the described embodiments of the present invention:

TABLE 1

| | | | |
|---|---|---|---|
| VCO | Voltage Controlled Oscillator | ICO | Current Controlled Oscillator |
| SoC | System on Chip | NRLVCO | Noise-regulated linear VCO |
| PSRR | Power Supply Rejection Ratio | SAW | Surface Acoustic Wave |
| Kvdd | Supply voltage gain | Kvco | Control voltage gain |
| PVT | Process, Voltage, Temperature | PLL | Phase-Locked Loop |
| PFET | P-channel Field Effect Transistor | Opamp | Operational Amplifier |
| V_{dd} | Positive supply voltage | Vₛₛ | Negative supply voltage/ground |
| V_{c} | VCO control voltage | Iₘᵢᵣᵣₒᵣ | mirror current |

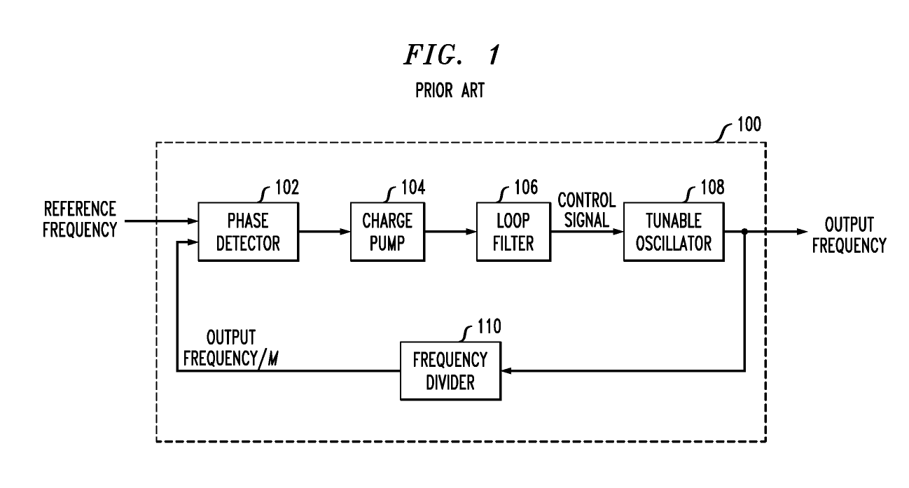

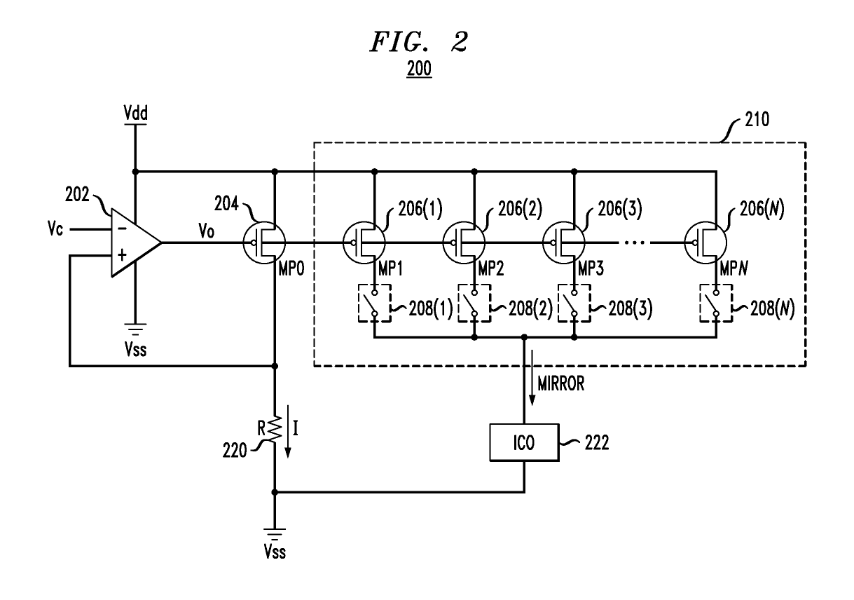

FIG. 2 shows a block diagram of an NRL VCO in accordance with embodiments of the present invention. As shown in FIG. 2, NRL VCO 200 might desirably employ opamp 202 and ICO 222 to achieve relatively high linearity. Additive noise of the power supply, Vdd, of NRL VCO 200 might be limited due to the PSRR of opamp 202. Feedback signals through opamp 202 might desirably provide for increased linearity of NRL VCO 200. As shown in FIG. 2, opamp 202 is provided with feedback to its non-inverting input by the voltage across resistor 220. The inverting input of opamp 202 is provided with the VCO control voltage, V_{c}. As shown in FIG. 1, control voltage V_{c} might typically be provided by a loop filter of a PLL. Opamp 202 receives positive and negative power supplies, V_{dd} and Vₛₛ, respectively.

The output, Vₒ, of opamp 202 is tied to the gate of PFET MP0 204. MP0 204 drives the current through resistor 220. As shown in FIG. 2, the circuit of opamp 202, MP0 204 and resistor 220 has a voltage gain substantially equal to 1 (substantially unity gain), thus, the voltage across resistor 220 is substantially equal to the input voltage to opamp 202. Therefore, the current, I, through resistor 220 and, thus, the current through MP0 204, is substantially equal to V_{c}/R, where R is the resistance value of resistor 220. In embodiments of the present invention, opamp 202 might be implemented as a folded cascode opamp having an NMOS input differential pair of transistors.

The current, I, through resistor 220 and MP0 204 is mirrored by current mirror 210. As shown, current mirror 210 might employ PFET MP1 206(1) up to PFET MPN 206(N), where N is an integer greater than 1. The mirror current is substantially equal to Iₘᵢᵣᵣₒᵣ=I_{MP1}+I_{MP2}+I_{MP3}+ . . . +I_{MPN}. The mirror current, Iₘᵢᵣᵣₒᵣ, is employed to control the oscillation frequency of ICO 222. As mirror current, Iₘᵢᵣᵣₒᵣ, increases, the frequency of ICO 222 increases, and vice-versa. Switches 208(1)-208(N) allow for frequency calibration of NRL VCO 200.

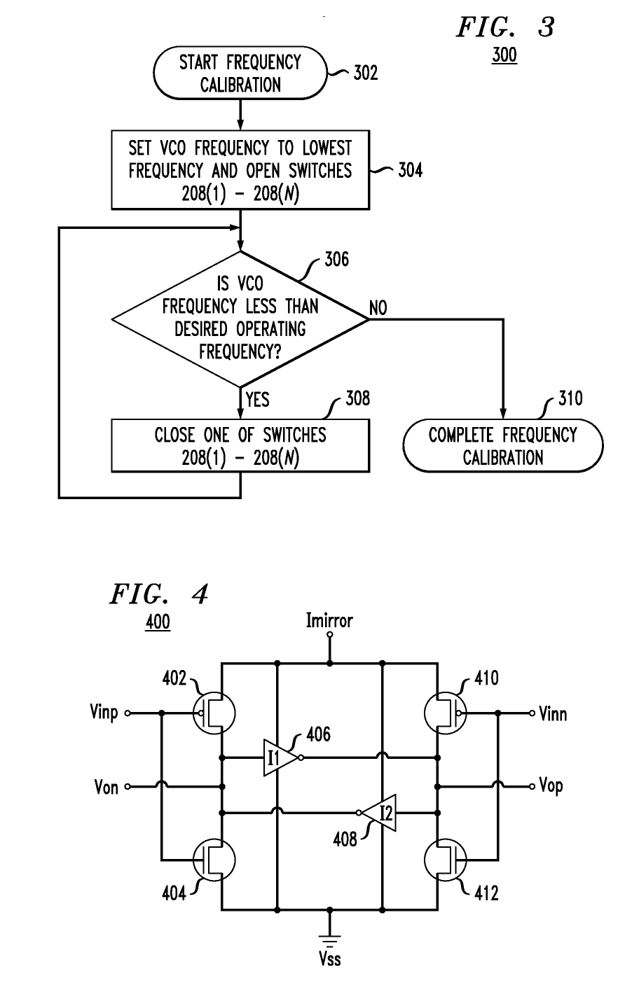

FIG. 3 shows a flow diagram of frequency calibration process 300 employed by NRL VCO 200. At step 302, frequency calibration of NRL VCO 200 is started. At step 304, the output signal frequency of NRL VCO 200 is set to a minimum value (e.g., all of switches 208(1)-208(N) are open). At step 306, the VCO's oscillation frequency is compared with the reference signal frequency. At step 306, if the frequency of NRL VCO 200 is lower than the desired frequency (e.g., M* reference frequency, where M is an integer greater than 0), at step 308 one or more of switches 208(1)-208(N) is closed, and the VCO frequency is again compared with the reference signal frequency at step 306. This adjustment through opening and closing various ones of switches 208(1)-208(N) might continue in an iterative loop until the frequency of VCO 200 reaches a desired threshold, such as when the output signal frequency is approximately equivalent to M* the reference frequency at step 306. For example, once the frequency of VCO 200 is greater than or equal to M* the reference frequency at step 306, frequency calibration process 310 ends at step 310.

Switches 208(1)-208(N) might be controlled by one or more switch control signals. The switch control signals might be based upon a value in a control register or digital logic of an SoC of which VCO 200 is a part. In exemplary embodiments of the present invention, VCO 200 might employ six switches (e.g., N=6), and the switch control signal might be 6 bits, each bit used to control a corresponding one of switches 208(1)-208(N). For example, in the case of a 6-bit switch control signal and 6 switches, VCO 200 might achieve a calibration accuracy of +/−5% of the desired VCO frequency. Switches 208(1)-208(N) might be located in either the source or drain path of corresponding transistors 206(1)-206(N) to decouple the corresponding transistor 206(1)-206(N) from current mirror 210. Switches 208(1)-208(N) might be implemented as mechanical, electromechanical or semiconductor switches. Alternatively, switches 208(1)-208(N) might be implemented as one or more corresponding switches coupled to the gate of each corresponding transistor 206(1)-206(N) employed to turn on or turn off a corresponding one of transistors 206(1)-206(N).

FIG. 4 shows an exemplary schematic diagram of delay cell 400 of ICO 222. Delay cell 400 includes PFETs 402 and 410 and NFETs 404 and 412. Transistors 402, 404, 410 and 412 are configured to form a differential inverter. Transistors 402 and 404 are coupled in series to provide negative output voltage Von at the junction of the drain of transistor 402 and the drain of transistor 404. Transistors 410 and 412 are coupled in series to provide positive output voltage Vop at the junction of the drain of transistor 410 and the drain of transistor 412. Positive control voltage Vinp is coupled to the gates of transistors 402 and 404, and negative control voltage Vinn is coupled to the gates of transistors 410 and 412. Inverter I1 406 and inverter I2 408 are cross-coupled between positive output voltage Vop and negative output voltage Von. Inverter I1 406 and inverter I2 408 are employed as enforcers to improve the symmetry of the output frequency waveform of VCO 200, thus, improving the phase noise of VCO 200. Current mirror 210 provides a current, Iₘᵢᵣᵣₒᵣ, to delay cell 400.

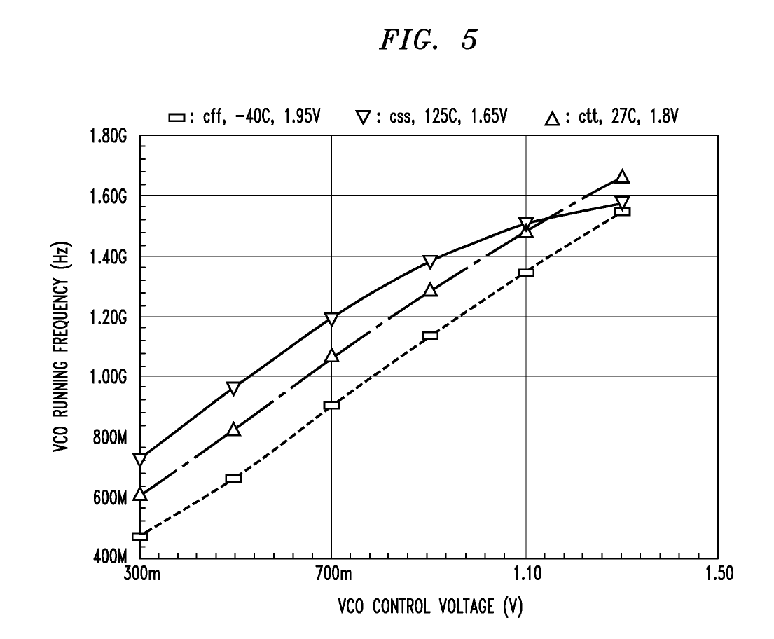

FIGS. 5-8 show exemplary performance plots of VCO 200 in the exemplary case when NRL VCO 200 is implemented as an 8 stage VCO using 45 nm technology, with a target frequency of operation of 1.25 GHz and a 1.8V supply voltage (e.g., V_{dd}=1.8V). FIG. 5 shows a plot of Kvco (e.g., VCO frequency versus control voltage) after frequency calibration is performed. As shown in FIG. 5, after frequency calibration, NRL VCO 200 exhibits high linearity and a Kvco value near 1 GHz/V. For example, for an exemplary nominal operating condition, “CTT”, having a temperature of 27 C and an operating voltage of 1.8V, the plot of FIG. 5 shows that the running frequency of NRL VCO 200 varies from 600 MHz to 1.65 GHz as the VCO control voltage, V_{c}, varies from 300 mV to 1.3V. FIG. 5 also shows two exemplary boundary operating conditions, “CFF” and “CSS”. For exemplary operating condition CFF, having a temperature of −40 C and an operating voltage of 1.95V, the plot of FIG. 5 shows that the running frequency of NRL VCO 200 varies from 500 MHz to 1.55 GHz as the VCO control voltage, V_{c}, varies from 300 mV to 1.3V. For exemplary operating condition CSS, having a temperature of 125 C and an operating voltage of 1.65V, the plot of FIG. 5 shows that the running frequency of NRL VCO 200 varies from 700 MHz to 1.55 GHz as the VCO control voltage, V_{c}, varies from 300 mV to 1.3V.

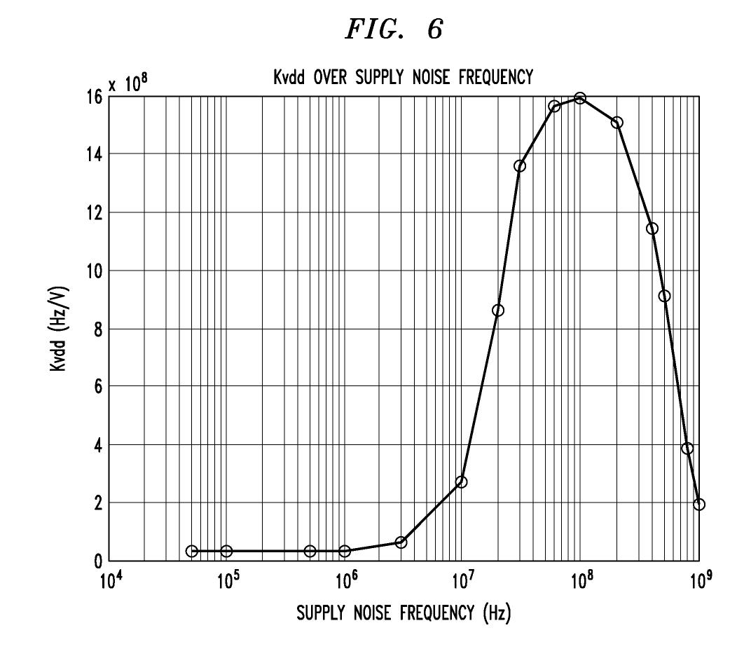

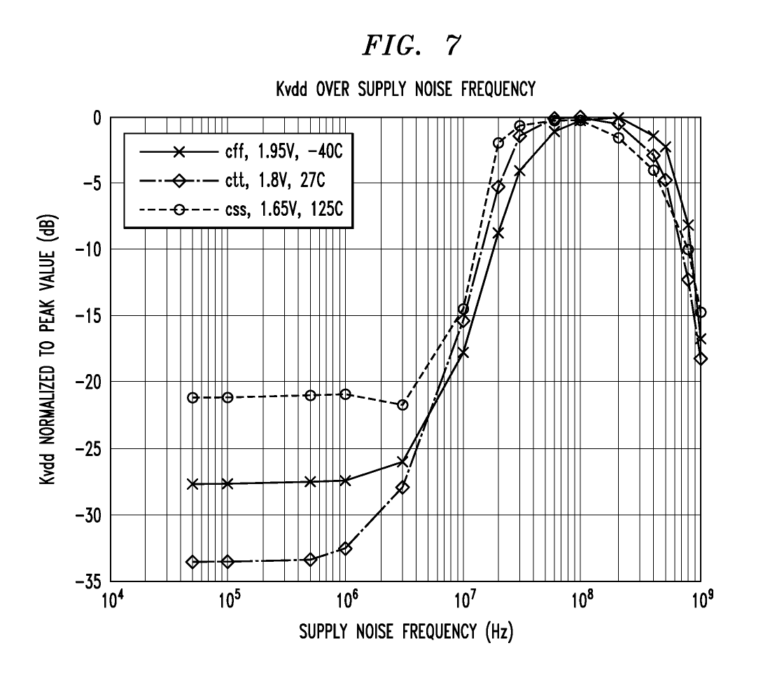

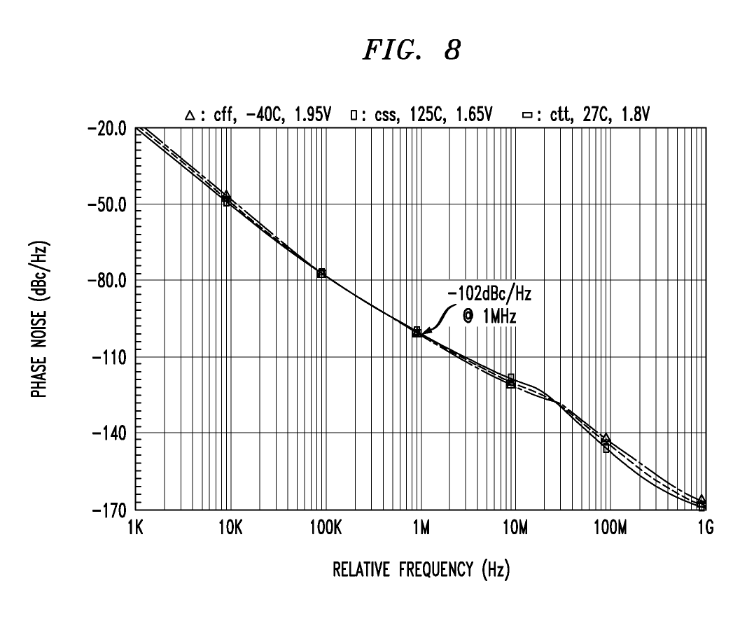

FIG. 6 shows an exemplary plot of Kvdd (power supply gain) versus power supply noise frequency. As shown in FIG. 6, as the supply noise frequency varies from 1 MHz to 1 GHz, Kvdd might reach a maximum of 1.6×10⁹ Hz/V at 100 MHz. FIG. 7 shows a similar plot as FIG. 6, showing a plot of three cases of Kvdd versus power supply noise frequency, normalized to the peak value for the three exemplary operating conditions of FIG. 5 (CSS, CFF and CTT). As shown in FIGS. 6 and 7, due to the PSRR of opamp 202, Kvdd is decreased at low frequency. For example, Kvdd is reduced by more than 20 dB for frequencies below 40 MHz. As shown in FIG. 7, for operating condition CSS, Kvdd is reduced by over 20 dB, for operating condition CFF, Kvdd is reduced by over 25 dB, and for operating condition CTT, Kvdd is reduced by over 30 dB. Thus, NRL VCO 200 exhibits PSRR comparable to VCO designs having a voltage regulator. Further, due to the limited bandwidth of opamp 202, the frequency modulation bandwidth is also decreased. In exemplary embodiments of the present invention, the bandwidth of opamp 202 might be selected to attenuate control voltage ripple without degrading stability of the PLL. FIG. 8 shows an exemplary plot of phase noise versus frequency of NRL VCO 200.

Phase noise is a measurement of random fluctuations in the phase of the VCO output signal. The lower the phase noise of a VCO, the closer the VCO is to an ideal signal source. As shown in FIG. 8, the phase noise of NRL VCO 200 at 1 MHz offset is approximately −102 dBc/Hz, which is good for a ring oscillator. Power consumption of NRL VCO 200 is approximately 10 mA. For the three exemplary operating conditions, CSS, CFF and CTT, as the relative frequency varies from 1 kHz to 1 GHz, the phase noise varies from −20 dBc/Hz to −170 dBc/Hz.

Thus, as described herein, embodiments of the present invention provide a VCO employing a unity gain opamp in conjunction with an ICO. The opamp provides PSRR for the VCO to achieve high power supply noise rejection. The ICO provides linearity of the VCO. High accuracy frequency calibration is provided via an adjustable current mirror supplying the ICO. Embodiments of the present invention also achieve low frequency modulation bandwidth, low control voltage gain variation and low phase noise.

While the exemplary embodiments of the present invention have been described with respect to processes of circuits, including possible implementation as a single integrated circuit, a multi-chip module, a single card, or a multi-card circuit pack, the present invention is not so limited.

As would be apparent to one skilled in the art, various functions of circuit elements might also be implemented as processing blocks in a software program. Such software might be employed in, for example, a digital signal processor, microcontroller, or general-purpose computer. Such software might be embodied in the form of program code embodied in tangible media, such as magnetic recording media, optical recording media, solid state memory, floppy diskettes, CD-ROMs, hard drives, or any other non-transitory machine-readable storage medium, wherein, when the program code is loaded into and executed by a machine, such as a computer, the machine becomes an apparatus for practicing the invention. When implemented on a general-purpose processor, the program code segments combine with the processor to provide a unique device that operates analogously to specific logic circuits. The present invention can also be embodied in the form of a bitstream or other sequence of signal values electrically or optically transmitted through a medium, stored magnetic-field variations in a magnetic recording medium, etc., generated using a method and/or an apparatus of the present invention.

It should be understood that the steps of the exemplary methods set forth herein are not necessarily required to be performed in the order described, and the order of the steps of such methods should be understood to be merely exemplary. Likewise, additional steps might be included in such methods, and certain steps might be omitted or combined, in methods consistent with various embodiments of the present invention.

As used herein in reference to an element and a standard, the term “compatible” means that the element communicates with other elements in a manner wholly or partially specified by the standard, and would be recognized by other elements as sufficiently capable of communicating with the other elements in the manner specified by the standard. The compatible element does not need to operate internally in a manner specified by the standard.

Unless explicitly stated otherwise, each numerical value and range should be interpreted as being approximate as if the word “about” or “approximately” preceded the value of the value or range. Signals and corresponding nodes or ports might be referred to by the same name and are interchangeable for purposes here.

Transistors are typically shown as single devices for illustrative purposes. However, it is understood by those skilled in the art that transistors will have various sizes (e.g., gate width and length) and characteristics (e.g., threshold voltage, gain, etc.) and might consist of multiple transistors coupled in parallel to get desired electrical characteristics from the combination. Further, the illustrated transistors might be composite transistors.

Also for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements. Signals and corresponding nodes or ports might be referred to by the same name and are interchangeable for purposes here.

It will be further understood that various changes in the details, materials, and arrangements of the parts which have been described and illustrated in order to explain the nature of this invention might be made by those skilled in the art without departing from the scope of the invention as expressed in the following claims.

1. A voltage controlled oscillator (VCO) comprising:
an operational amplifier (opamp) having a positive power supply input, a negative power supply input, an inverting input, a noninverting input and an output providing a transistor control voltage, wherein the positive power supply input is coupled to a power supply voltage, the negative power supply input is coupled to a ground node, the inverting input is coupled to a control voltage of the VCO, and the noninverting input receives a feedback signal;
a transistor having a gate terminal, a source terminal and a drain terminal, the gate terminal coupled to the output of the opamp, the source terminal coupled to the power supply voltage, and the drain terminal coupled to a resistor coupled to ground, the resistor configured to generate an output current;
a current mirror including N switches, wherein N is an integer greater than 1, and configured to generate a mirror current based on the output current; and
a current controlled oscillator (ICO) coupled to the current mirror, the ICO configured to set the frequency of the VCO output signal based upon the mirror current,
wherein high accuracy frequency calibration is provided through comparing the frequency of the VCO output signal with a reference signal frequency via opening and closing various ones of the N switches in the current mirror.

2. The VCO of claim 1, wherein the opamp is configured with substantially unity gain.

3. The VCO of claim 1, wherein the transistor is a P-channel Field Effect Transistor (PFET).

4. The VCO of claim 1, wherein the current mirror comprises:
N transistors, each transistor having a gate terminal, a source terminal and a drain terminal, each source terminal coupled to the power supply voltage, each gate terminal coupled to the opamp output, and each drain terminal coupled to a corresponding one of the N switches, the N switches configured to selectively couple the corresponding drain terminal to the ICO.

5. The VCO of claim 4, wherein the N transistors are P-channel Field Effect Transistors (PFETs).

6. The VCO of claim 4, wherein the N switches are controlled by one or more control signals of the VCO.

7. The VCO of claim 6, wherein the N switches are controlled by corresponding bits of the one or more control signals of the VCO.

8. The VCO of claim 4, wherein the current mirror is configured to provide for frequency calibration of the VCO by adjusting the N switches to increase or decrease the mirror current provided to the ICO, wherein the mirror current increases as each of the N switches are closed and the output frequency of the ICO increases as the mirror current increases.

9. The VCO of claim 8, wherein, after frequency calibration of the VCO is complete, the VCO is configured to provide frequency tuning by adjusting the control voltage of the VCO wherein the output current increases as the control voltage of the VCO is increased.

10. The VCO of claim 1, wherein the ICO comprises one or more delay cells, the delay cells comprising:
a first transistor pair coupled to a positive input voltage, the first transistor pair configured to generate a negative output voltage based on the mirror current;
a second transistor pair coupled to a negative input voltage, the second transistor pair configured to generate a positive output voltage based on the mirror current; and
a first inverter and a second inverter cross-coupled between the positive output voltage and the negative output voltage, wherein the positive output voltage and the negative output voltage form an output frequency of the ICO, and wherein the first and second inverters are configured to provide symmetry of the output frequency waveform of the ICO.

11. The VCO of claim 1, wherein:
the opamp is configured to provide power supply ripple rejection for the VCO; and the ICO is configured to provide linearity of the output frequency of the VCO.

12. The VCO of claim 1, wherein the VCO is implemented in an integrated circuit.

13. A method of frequency calibrating a voltage controlled oscillator (VCO), the VCO comprising an operational amplifier (opamp) coupled to a control voltage of the VCO, a transistor having its gate terminal coupled to the output of the opamp, its source terminal coupled to a power supply voltage, and its drain terminal coupled to a resistor to generate a feedback signal to the opamp and an output current, a current mirror configured to generate a current based on the output current, the current mirror comprising N transistors, each transistor having a source terminal coupled to the power supply voltage, a gate terminal coupled to the output of the opamp, and a drain terminal coupled to a corresponding one of N switches, wherein N is an integer greater than 1, each of the N switches coupled to a current controlled oscillator (ICO), the ICO configured to set the frequency of the VCO output signal based upon the mirror current, wherein high accuracy frequency calibration is provided through comparing the frequency of the VCO output signal with a reference signal frequency via opening and closing various ones of the N switches in the current mirror, the method comprising:
setting a current of the current mirror to a minimum value by opening the N switches of the current mirror;
iteratively (i) determining whether the output frequency of the VCO is less than a desired frequency of the VCO, and, if the output frequency of the VCO is less that the desired frequency, (ii) closing one of the N switches to couple the drain terminal of the corresponding transistor to the ICO to increases the current of the current mirror, wherein increasing the current of the current mirror increases the output frequency.

14. The method of claim 13, wherein the opamp is configured to have unity gain.

15. The method of claim 13, wherein the transistors are P-channel Field Effect Transistors (PFETs).

16. The method of claim 13, further comprising:
controlling the N switches of the current mirror by one or more control signals of the VCO.

17. The method of claim 16, wherein the N switches are controlled by corresponding bits of the one or more control signals of the VCO.

18. The method of claim 13, wherein the ICO comprises one or more delay cells, the method further comprising:
generating a negative output voltage based on the mirror current by a first transistor pair of the delay cell, the first transistor pair coupled to a positive input voltage;
generating a positive output voltage based on the mirror current by a second transistor pair of the delay cell, the second transistor pair coupled to a negative input voltage; and
providing symmetry of the output frequency waveform of the ICO by a first inverter and a second inverter cross-coupled between the positive output voltage and the negative output voltage, wherein the positive output voltage and the negative output voltage form an output frequency of the ICO.

19. The method of claim 13, comprising:
providing, by the opamp, power supply ripple rejection for the VCO; and
providing, by the ICO, linearity of the output frequency of the VCO.

20. The method of claim 13, further comprising:
tuning the frequency of the VCO by adjusting the control voltage of the VCO, wherein the output current increases as the control voltage of the VCO is increased.
